(19) United States
(12) Patent Application Publication
(10) Pub. No.: US 2008/0169024 A1
(43) Pub. Date: Jul. 17, 2008

(54) PHOTOVOLTAIC DEVICE

(76) Inventor: Jin-Yuan Lee, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/847,346

(22) Filed: Aug. 30, 2007

(30) Foreign Application Priority Data
Jan. 12, 2007 (TW) 96101259

(51) Int. Cl. H01L 31/00

(52) U.S. Cl. 136/261

(57) ABSTRACT

A photovoltaic device which includes a first type doped single crystal silicon substrate, a second type doped silicon layer, an intrinsic silicon layer, a first metal electrode layer, and a second metal electrode layer. The intrinsic silicon layer is disposed between the first type doped single crystal silicon substrate and the second type doped silicon layer. The thickness of the intrinsic silicon layer is between 10 μm and 100 μm. The first metal electrode layer is disposed on a first surface of the first type doped single crystal silicon substrate away from the intrinsic silicon layer. The second metal electrode layer is disposed on a second surface of the second type doped silicon layer away from the intrinsic silicon layer.

### CROSS-REFERENCE TO RELATED APPLICATION

This application claims the priority benefit of Taiwan application serial no. 96101259, filed Jan. 12, 2007. All disclosure of the Taiwan application is incorporated herein by reference.

### BACKGROUND OF THE INVENTION

1. Field of the Invention

The present invention relates to a semiconductor device. More particularly, the present invention relates to a photovoltaic device.

2. Description of Related Art

Conventional electric power generation methods by means of consuming petrochemical fuel or nuclear energy not only produce pollution but also consume natural resources. To avoid environment pollution and natural disaster caused by global warming, the demand of renewable resources keeps increasing. Energy substitute for utilizing solar energy has become most important because solar energy is clean and inexhaustible.

FIG. 1 demonstrates a schematic cross section view of a conventional photovoltaic device. Referring to FIG. 1, the conventional photovoltaic device 100 includes a P-type doped silicon layer 110 which is a silicon layer doped with acceptor impurities and an N-type doped silicon layer 120 which is a silicon layer doped with donor impurities. The P-type doped silicon layer 110 is a boron-doped single crystal silicon layer or a boron-doped poly crystal silicon layer mainly. The N-type doped silicon layer 120 is disposed on the P-type doped silicon layer 110, and the thickness t1 of the N-type doped silicon layer 120 is less than the thickness t2 of the P-type doped silicon layer 110 so that most of sunlight can pass through the N-type doped silicon layer 120 and be adsorbed in P-type doped silicon layer 110. The N-type doped silicon layer 120 is a phosphor-doped silicon layer in general.

The interface between the P-type doped silicon layer 110 and the N-type doped silicon layer 120 of the photovoltaic device 100 is called PN junction. There is a depletion region 10 close to PN junction because electrons in the N-type doped silicon layer 120 diffuse into the P-type doped silicon layer 110 to recombine with holes in the P-type doped silicon layer 110, and holes in the P-type doped silicon layer 110 also diffuse into N-type doped silicon layer 120 to recombine with electrons in the N-type doped silicon layer 120. The diffusion of electrons and holes does not happen infinitely because of a built-in electric field f1 which is created by the imbalance of charge immediately either side of the junction which this diffusion creates. While sunlight irradiates into the conventional photovoltaic device 100, a few ratio of photons adsorbed in the depletion region 10 and most of photons adsorbed in the P-type layer 110 to generate electron-hole pairs. Those electrons and holes, generated in depletion region 10, move in the photovoltaic device 100 under the affection of the built-in electric field f1 directly. To be specific, electrons move against the direction of the built-in electric field f1, while holes move along the direction of the built-in electric field f1. Some electrons of electron-hole pairs generated in the P-type layer 110 diffuse to depletion region 10 and drifted by built-in electric field f1. Therefore, the photovoltaic device 100 generates useful electric current.

As described above, those electron-hole pairs generated in depletion region 10 can be converted to useful electric current effectively. Those electron-hole pairs generated in the P-type layer 110 may not be converted to useful electric current because electrons may be recombined before they diffuse to depletion region 10. However, the width of the depletion region 10 in conventional photovoltaic device100 is very narrow, less than 1 μm. So most of incident sunlight is not adsorbed in the depletion region 10, therefore the photoelectric efficiency of conventional photovoltaic device 100 is limited.

### SUMMARY OF THE INVENTION

The present invention demonstrates a photovoltaic device having high photoelectric efficiency.

The present invention provides a first type photovoltaic device which includes a first type doped single crystal silicon substrate, a second type doped silicon layer, an intrinsic silicon layer, a first metal electrode layer, and a second metal electrode layer. The intrinsic silicon layer is disposed between the first type doped single crystal silicon substrate and the second type doped silicon layer. The thickness of the intrinsic silicon layer is between 10 μm and 100 μm. The first metal electrode layer is disposed on a first surface of the first type doped single crystal silicon substrate away from the intrinsic silicon layer. The second metal electrode layer is disposed on a second surface of the second type doped silicon layer away from the intrinsic silicon layer.

According to an embodiment of the first type photovoltaic device of the present invention, the first type doped single crystal silicon substrate is a P-type doped single crystal silicon substrate, and the second type doped silicon layer is an N-type doped silicon layer.

According to an embodiment of the first type photovoltaic device of the present invention, the first type doped single crystal silicon substrate may also be an N-type doped single crystal silicon substrate, and the second type doped silicon layer is a P-type doped silicon layer.

According to an embodiment of the first type photovoltaic device of the present invention, the thickness of the first type doped single crystal silicon substrate is between 80 μm and 200 μm.

According to an embodiment of the first type photovoltaic device of the present invention, the thickness of the second type doped silicon layer is between 0.05 μm and 0.5 μm.

According to an embodiment of the first type photovoltaic device of the present invention, the material of the second type doped silicon layer includes single crystal silicon or poly crystal silicon.

According to an embodiment of the first type photovoltaic device of the present invention, the material of the intrinsic silicon layer includes single crystal silicon or poly crystal silicon.

According to an embodiment of the first type photovoltaic device of the present invention, the first type doped single crystal silicon substrate has a third surface in contact with the intrinsic silicon layer and the maximum height roughness of the third surface of the first type doped single crystal silicon substrate is between 0.01 μm and 10 μm.

According to an embodiment of the first type photovoltaic device of the present invention, if the intrinsic silicon layer is doped with a small quantity of acceptor impurities and/or a small quantity of donor impurities, the difference between the concentration of the acceptor impurities and that of the donor impurities is less than 10 ppb and preferred to be less than 1 ppb.

The present invention provides a second type photovoltaic device which includes a first type doped silicon layer, a second type doped silicon layer, an intrinsic silicon substrate, a first metal electrode layer, and a second metal electrode layer. The intrinsic silicon substrate is disposed between the first type doped silicon layer and the second type doped silicon layer. The thickness of the intrinsic silicon substrate is between 50 μm and 200 μm. The first metal electrode layer is disposed on a first surface of the first type doped silicon layer away from the intrinsic silicon substrate. The second metal electrode layer is disposed on a second surface of the second type doped silicon layer away from the intrinsic silicon substrate.

According to an embodiment of the second type photovoltaic device of the present invention, the first type doped silicon layer is a P-type doped silicon layer, and the second type doped silicon layer is an N-type doped silicon layer.

According to an embodiment of the second type photovoltaic device of the present invention, the first type doped silicon layer may also be an N-type doped silicon layer, and the second type doped silicon layer is a P-type doped silicon layer.

According to an embodiment of the second type photovoltaic device of the present invention, the thickness of the first type doped silicon layer is between 0.3 μm and 10 μm.

According to an embodiment of the second type photovoltaic device of the present invention, the thickness of the second type doped silicon layer is between 0.03 μm and 1 μm.

According to an embodiment of the second type photovoltaic device of the present invention, the preferable thickness of the first type doped silicon layer is between 0.3 μm and 1 μm.

According to an embodiment of the second type photovoltaic device of the present invention, the thickness of the second type doped silicon layer is between 0.05 μm and 0.5 μm.

According to an embodiment of the second type photovoltaic device of the present invention, the material of the first type doped silicon layer includes single crystal silicon or poly crystal silicon.

According to an embodiment of the second type photovoltaic device of the present invention, the material of the second type doped silicon layer includes single crystal silicon or poly crystal silicon.

According to an embodiment of the second type photovoltaic device of the present invention, the intrinsic silicon substrate has a third surface in contact with the first type doped silicon layer and the maximum height roughness of the third surface of the intrinsic silicon substrate is between 0.01 μm and 10 μm.

According to an embodiment of the second type photovoltaic device of the present invention, the maximum height roughness of the second surface of the second type doped silicon layer is between 0.01 μm and 10 μm.

According to an embodiment of the second type photovoltaic device of the present invention, if the intrinsic silicon substrate is doped with a small quantity of acceptor impurities and/or a small quantity of donor impurities, the difference between the concentration of the acceptor impurities and that of the donor impurities is less than 10 ppb and preferred to be less than 1 ppb.

The present invention provides a third type photovoltaic device which includes an N-type doped silicon layer, a first electrode layer, an intrinsic silicon layer, and a second electrode layer. The first electrode layer has a conductive layer, and the work function of the conductive layer is higher than 5.5 eV. The intrinsic silicon layer is disposed between the doped silicon layer and the first electrode layer, wherein the conductive layer is in direct contact with the intrinsic silicon layer. The second electrode layer is disposed on a first surface of the doped silicon layer away from the intrinsic silicon layer.

According to an embodiment of the third type photovoltaic device of the present invention, the material of the conductive layer includes platinum.

According to an embodiment of the third type photovoltaic device of the present invention, the thickness of the N-type doped silicon layer is between 0.05 μm and 1 μm.

According to an embodiment of the third type photovoltaic device of the present invention, the thickness of the first electrode layer is between 0.031 μm and 10 μm.

According to an embodiment of the third type photovoltaic device of the present invention, the thickness of the N-type doped silicon layer is between 0.05 μm and 0.5 μm.

According to an embodiment of the third type photovoltaic device of the present invention, the thickness of the conductive layer is between 0.05 μm and 0.3 μm.

According to an embodiment of the third type photovoltaic device of the present invention, the thickness of the intrinsic silicon layer is between 1 μm and 400 μm.

According to an embodiment of the third type photovoltaic device of the present invention, the material of the doped silicon layer includes single crystal silicon or poly crystal silicon.

According to an embodiment of the third type photovoltaic device of the present invention, if the intrinsic silicon layer is doped with a small quantity of acceptor impurities and or a small quantity of donor impurities, the difference between the concentration of the acceptor impurities and that of the donor impurities is less than 10 ppb and preferred to be less than 1 ppb.

As described above, a photovoltaic device in the present invention has an intrinsic silicon region so the thickness of the depletion region becomes very large and most of incident sunlight absorbed in the intrinsic silicon region. Therefore, the photovoltaic device in the present invention has high photoelectric efficiency.

In order to make the aforementioned and other objects, features and advantages of the present invention comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 demonstrates a schematic cross section view of a conventional photovoltaic device.

FIG. 2 demonstrates a schematic cross section view of a photovoltaic device according to a first embodiment of the present invention.

FIGS. 3A˜3C demonstrates schematic cross section views illustrating the process flow for manufacturing the photovoltaic device according to the first embodiment of the present invention.

FIG. 4 demonstrates a schematic cross section view of a photovoltaic device according to a second embodiment of the present invention.

FIGS. 5A˜5C demonstrates schematic cross section views illustrating the process flow for manufacturing the photovoltaic device according to the second embodiment of the present invention.

FIG. 6 demonstrates a schematic cross section view of a photovoltaic device according to a third embodiment of the present invention.

FIGS. 7A˜7C demonstrates schematic cross section views illustrating process flow for manufacturing the photovoltaic device according to the third embodiment of the present invention.

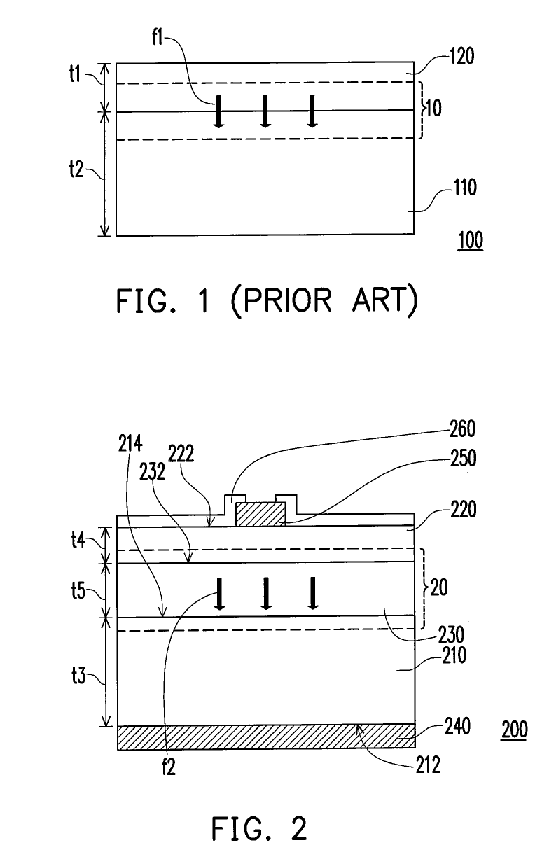

### DESCRIPTION OF EMBODIMENTS

### First Embodiment

FIG. 2 demonstrates a schematic cross section view of a photovoltaic device according to a first embodiment of the present invention. Referring to FIG. 2, the photovoltaic device 200 includes a first type doped single crystal silicon substrate 210, a second type doped silicon layer 220, an intrinsic silicon layer 230, a first metal electrode layer 240, and a second metal electrode layer 250. The intrinsic silicon layer 230 is disposed between the first type doped single crystal silicon substrate 210 and the second type doped silicon layer 220. The thickness t5 of the intrinsic silicon layer is between 10 μm and 100 μm. The first metal electrode layer 240 is disposed on a surface 212 of the first type doped single crystal silicon substrate 210 away from the intrinsic silicon layer 230. The second metal electrode layer 250 is disposed on a surface 222 of the second type doped silicon layer 220 away from the intrinsic silicon layer 230.

Since the intrinsic silicon layer 230 is disposed between the first type doped single crystal silicon substrate 210 and the second type doped silicon layer 220, the photovoltaic device 200 has a larger depletion region 20 therein. While sunlight irradiates the photovoltaic device 200 from the top surface of the second doped silicon layer 220, most of sunlight is absorbed and electron-hole pairs are generated in the depletion region 20 since photovoltaic device 200 has thin second type doped silicon layer 220 and thick depletion region 20. These electron-hole pairs generated in depletion region 20 can be drifted by the built-in electric field f2 and transfer to useful electric current. Since the electric current is drifted current mainly but not diffusion current, the photovoltaic device 200 has high photoelectric efficiency.

In the present embodiment, the first type doped single crystal silicon substrate 210 is a P-type doped single crystal silicon substrate (for example, a boron-doped single crystal silicon substrate), and the second type doped silicon layer 220 is an N-type doped silicon layer (for example, a phosphor-doped or arsenic-doped single crystal silicon layer, or a phosphor-doped or arsenic-doped poly crystal silicon layer). Thus, the direction of the built-in electric field f2 is from the second type doped silicon layer 220 (N-type doped silicon layer) to the first type doped single crystal silicon substrate 210 (P-type doped single crystal silicon substrate). Besides, the material of the intrinsic silicon layer 230 includes single crystal silicon or poly crystal silicon. The intrinsic silicon layer 230 may be replaced by a lightly doped layer with acceptor impurities and donor impurities, and the concentration difference between acceptor impurities and donor impurities is less than 10 ppb and preferred to be less than 1 ppb. In addition, in another embodiment of the present invention, the first type doped single crystal silicon substrate 210 may be an N-type doped single crystal silicon substrate, and the second type doped silicon layer 220 is a P-type doped silicon layer. The doped level of silicon substrate 210 is larger than 10¹⁶ per cm³ and the doped level of silicon layer 220 is larger than 10¹⁸ per cm³ preferably.

It should be noted here that external sunlight usually irradiates the photovoltaic device 200 from the place above the photovoltaic device 200; namely, in the present embodiment, the external sunlight has to pass through the second type doped silicon layer 220 to reach the depletion region 20. Thus, the photovoltaic device 200 has better photoelectric efficiency when the thickness t4 of the second type doped silicon layer 220 is thinner. In other words, in the present embodiment, the thickness t3 of the first type doped single crystal silicon substrate 210 may be greater than the thickness t4 of the second type doped silicon layer 220 and the thickness t5 of the intrinsic silicon layer 230 may be greater than the thickness t4 of the second type doped silicon layer 220, so that the photovoltaic device 200 may have high photoelectric efficiency and sufficient mechanical strength.

To be specific, the thickness t3 of the first type doped single crystal silicon substrate 210 may be between 80 μm and 800 μm, and preferably, the thickness t3 of the first type doped single crystal silicon substrate 210 is between 80 μm and 200 μm. The thickness t4 of the second type doped silicon layer 220 may be between 0.03 μm and 1 μm, and preferably, the thickness t4 of the second type doped silicon layer 220 may be between 0.05 μm and 0.5 μm.

It has to be mentioned here that in the present embodiment, the surface 222 is designed as a rough surface in order to increase the possibility of the sunlight passing through the second type doped silicon layer 220 (i.e. to reduce the light reflectivity of the surface 222 of the second type doped silicon layer 220 away from the intrinsic silicon layer 230), wherein the maximum height roughness of the surface 222 may be between 0.01 μm and 10 μm. A surface 232 of the intrinsic silicon layer 230 in contact with the second type doped silicon layer 220 may also be a rough surface, and the maximum height roughness thereof may be between 0.01 μm and 10 μm, so that the light reflectivity of the surface 232 may be reduced and accordingly the possibility of sunlight reaching the depletion region 20 may be increased. Besides, the rough surface 232 also increases the contact area between the second type doped silicon layer 220 and the intrinsic silicon layer 230 so that the range of the depletion region 20 is increased. In addition, in the present embodiment, a surface 214 of the first type doped single crystal silicon substrate 210 in contact with the intrinsic silicon layer 230 may also be a rough surface in order to increase the range of the depletion region 20, and the maximum height roughness of the surface 214 may be between 0.01 μm and 10 μm.

In the present embodiment, the photovoltaic device 200 further includes an anti-reflective layer 260. The anti-reflective layer 260 is disposed on the second type doped silicon layer 220 and exposes the second metal electrode layer 250. The first metal electrode layer 240 and the second metal electrode layer 250 are used for connecting a load circuit (not shown). The material of the anti-reflective layer 260 includes silicon nitride, and the anti-reflective layer 260 is used for further reducing the light reflectivity of external sunlight. The thickness of the anti-reflective layer 260 may be between 0.1 μand 10 μm.

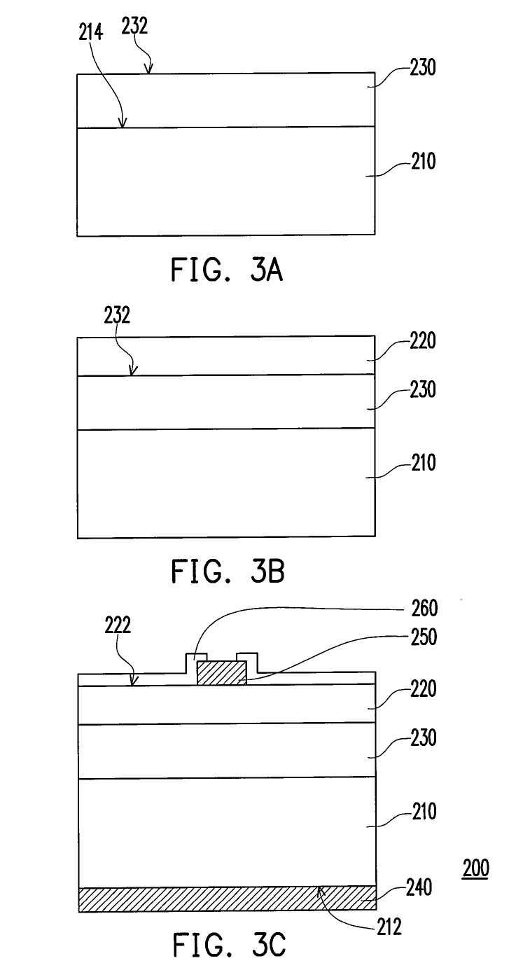

A method of manufacturing the photovoltaic device 200 in the present embodiment will be described. FIGS. 3A˜3C demonstrates schematic cross section views illustrating of the process flow for manufacturing the photovoltaic device according to the first embodiment of the present invention. First, referring to FIG. 3A, the intrinsic silicon layer 230 is deposited on the surface 214 of the first type doped single crystal silicon substrate 210 through chemical vapor deposition (CVD). An etching process may be conducted to form a rough surface 214 before deposition of intrinsic silicon layer 230. The etching process can be performed with solution containing KOH or NaOH.

The intrinsic silicon layer 230 can be single crystal structure and may be formed on the surface 214 by the following two methods. One method is through an epitaxy process carried out in a temperature between 950° C. and 1200° C., and in the environment containing SiH₄, or SiH₃Cl, or SiH₂Cl₂, or the mixture gas of SiHCl₃ and H₂, or the mixture gas of SiCl₄ and H₂. The other method is through amorphous silicon deposition and solid state epitaxial grain growth. Amorphous silicon is deposited by using CVD , or plasma enhanced CVD with reactive gas containing SiH₄, or SiH₃Cl, or SiH₂Cl₂ in a temperature between 250° C. and 580° C. After that, epitaxial grain growth of the amorphous silicon is carried out in a temperature between 590° C. and 650° C. An annealing process may be conducted to reduce crystal defect of epitaxy layer. The annealing process is carried out in an environment containing H₂ under a temperature between 900° C. and 1100° C.

The intrinsic silicon layer 230 can be poly crystal structure and may be formed on the surface 214 by the following two methods. One method is through amorphous silicon deposition and grain growth, and the other one is through poly crystal silicon deposition. For the method of the amorphous silicon deposition and grain growth process, amorphous silicon is deposited on the surface 214 by using CVD or PECVD with reactive gas containing SiH₄, SiH₃Cl, or SiH₂Cl₂ in a temperature between 250° C. and 580° C. And then grain growth of the amorphous silicon is carried out in a temperature between 700° C. and 900° C. For the method of the poly crystal silicon deposition process, poly crystal silicon is deposited on the surface 214 by using CVD or PECVD with reactive gas containing SiH₄, SiH₃Cl, or SiH₂Cl₂ in a temperature between 590° C. and 650° C.

An etching process may be conducted to form a rough surface 232 after deposition of intrinsic silicon layer 230. The etching process can be performed with solution containing KOH or NaOH.

Thereafter, referring to FIG. 3B, the second type doped silicon layer 220 is formed on the surface 232 of the intrinsic silicon layer 230 through ion implantation, diffusion, or in-situ doped CVD, wherein in-situ doped CVD is the preferred option for forming thin second type doped silicon layer 220 with low-resistance (high doping level) and reasonable manufacturing cost. The doped type of silicon layer 220 is N-type as the substrate 210 is P-type. On the other hand, the doped type of silicon layer 220 is P-type as the substrate 210 is N-type. For the second type doped silicon layer 220 such as an N-type doped silicon layer, the in-situ doped CVD process may be carried out with reactive gas containing PH₃ and SiH₄ or SiH₃Cl or SiH₂Cl₂ in a temperature between 590° C. and 650° C. and diffusion process may be carried out by using conventional POCL doping, or coating with phosphor containing glass and performing solid state diffusion in a temperature between 900° C. and 1100° C. For the second type doped silicon layer 220 such as a P-type doped silicon layer, the in-situ doped CVD process may be carried out with reactive gas containing BH₃ and SiH₄ or SiH₃Cl or SiH₂Cl₂ in a temperature between 590° C. and 650° C. and diffusion process can be carried out by coating with boron containing glass and performing solid state diffusion in a temperature between 900° C. and 1100° C.

Next, referring to FIG. 3C, the first metal electrode layer 240 and the second metal electrode layer 250 are sequentially respectively formed on the surface 212 of the first type doped single crystal silicon substrate 210 and the surface 222 of the second type doped silicon layer 220, wherein the second metal electrode layer 250 is formed through a patterning process. After that, referring to FIG. 3C again, an anti-reflective layer 260 is formed on the surface 222 of the second type doped silicon layer 220, and the anti-reflective layer 260 exposes a portion of the second metal electrode layer 250. The anti-reflective layer 260 may also be formed on the second type doped silicon layer 220 before formation of the second metal electrode layer 250, wherein the anti-reflective layer 260 exposes part of the second type doped silicon layer 220, and the second metal electrode layer 250 is formed on the exposed silicon layer 220. However, such an implementation is not shown in any drawing.

### Second Embodiment

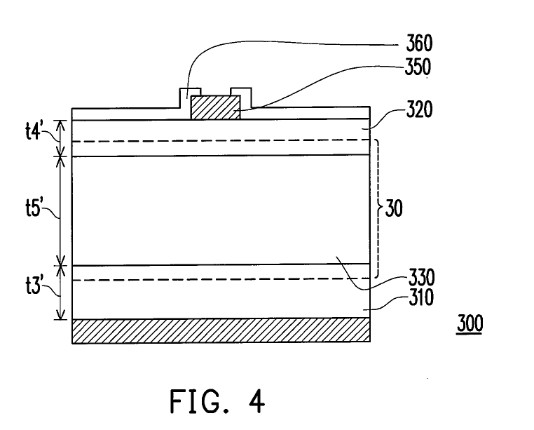

FIG. 4 demonstrates a schematic cross section view of a photovoltaic device according to a second embodiment of the present invention. Referring to FIG. 4, the photovoltaic device 300 has an intrinsic silicon substrate 330 of which the thickness t5′ is between 50 μm and 200 μm. In the present embodiment, the thickness t3′ of the first type doped silicon layer 310 may be between 0.3 μm and 10 μm, and preferably, the thickness t3′ of the first type doped silicon layer 310 is between 0.3 μm and 1 μm. The thickness t4′ of the second type doped silicon layer 320 may be between 0.03 μm and 1 μm, and preferably, the thickness t4′ of the second type doped silicon layer 320 may be between 0.05 μm and 0.5 μm.

It should be noted that external sunlight passes through silicon layer 320 and then is absorbed and electron-hole pairs are generated in the depletion region 30, so thinner thickness t4′ of silicon layer 320 has better efficiency. However, the internal resistance becomes higher as the thickness t4′ becomes thinner, so the preferred thickness t4′ of the second type doped silicon layer 320 is between 0.05 μm and 0.5 μm.

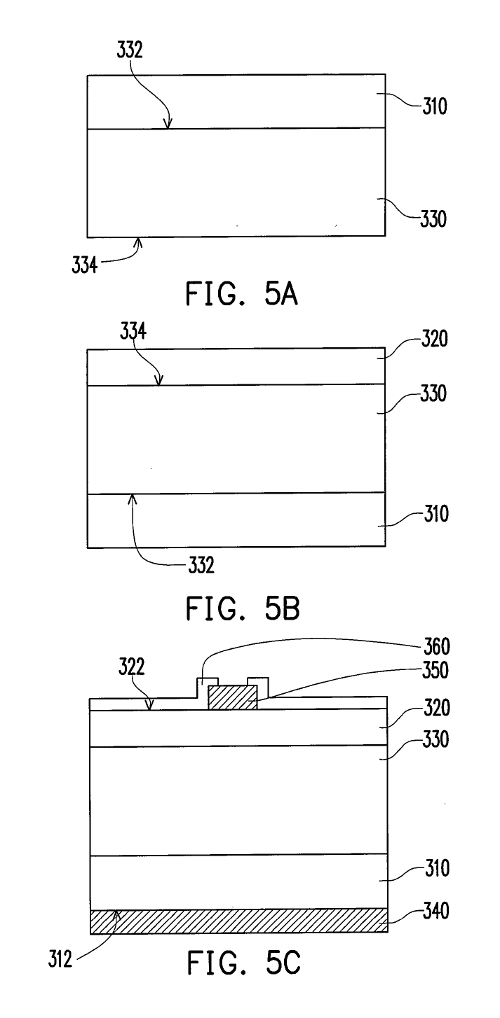

A method of manufacturing the photovoltaic device 300 in the present embodiment will be described. FIGS. 5A˜5C demonstrates schematic cross section views illustrating the process flow for manufacturing the photovoltaic device according to the second embodiment of the present invention. First, referring to FIG. 5A, the first type doped silicon layer 310 is deposited on a surface 332 of the intrinsic silicon substrate 330 through ion implantation, diffusion, or in-situ doped CVD. The diffusion and in-situ doped CVD process can be conducted by using the same process conditions for photovoltaic device 200. An etching process may be conducted to form two opposite rough surfaces 332 and 334 of the intrinsic silicon substrate 330 before deposition of the first type doped silicon layer 310. The etching process can be performed with solution containing KOH or NaOH. The maximum height roughness of the surface 332 and that of the surface 334 may be between 0.01 μm and 10 μm respectively.

Next, referring to FIG. 5B, the second type doped silicon layer 320 may be formed on the surface 334 of the intrinsic silicon substrate 330 through ion implantation, diffusion, or in-situ doped CVD. The diffusion and in-situ doped CVD process can be conducted by using the same process conditions for photovoltaic device 200.

Next, referring to FIG. 5C, a first metal electrode layer 340 and a second metal electrode layer 350 are sequentially respectively formed on a surface 312 of the first type doped silicon layer 310 and a surface 322 of the second type doped silicon layer 320, wherein the second metal electrode layer 350 is formed through a patterning process. After that, an anti-reflective layer 360 is formed on the surface 322 of the second type doped silicon layer 320 and the anti-reflective layer 360 exposes a portion of the second metal electrode layer 350.

### Third Embodiment

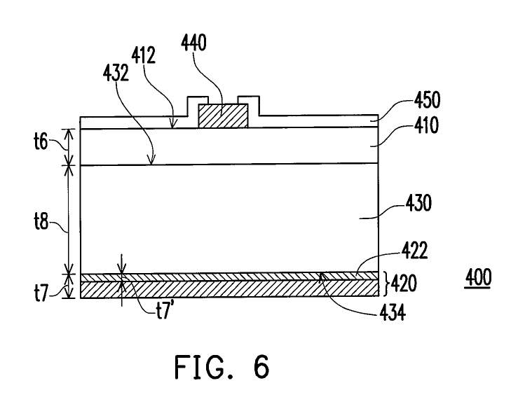

FIG. 6 demonstrates a schematic cross section view of a photovoltaic device according to a third embodiment of the present invention. Referring to FIG. 6, the photovoltaic device 400 includes an N-type doped silicon layer 410, a first electrode layer 420, an intrinsic silicon layer 430, and a second electrode layer 440. The first electrode layer 420 has a conductive layer 422 (for example, platinum), and the work function of the conductive layer 422 is higher than 5.5 eV. The intrinsic silicon layer 430 is disposed between the N-type doped silicon layer 410 and the first electrode layer 420, and the conductive layer 422 is in direct contact with the intrinsic silicon layer 430. The second electrode layer 440 is disposed on a surface 412 of the N-type doped silicon layer 410 away from the intrinsic silicon layer 430.

In the present embodiment, since the conductive layer 422 having work function higher than 5.5 eV is in direct contact with the intrinsic silicon layer 430, the photovoltaic device 400 has higher built-in voltage. Therefore, the photovoltaic device 400 has higher photoelectric efficiency.

In the present embodiment, the thickness t6 of the N-type doped silicon layer 410 may be between 0.05 μm and 1 μm, and preferably, the thickness t6 of the N-type doped silicon layer 410 may be between 0.05 μm and 0.5 μm. The thickness t7 of the first electrode layer 420 may be between 0.03 μm and 10 μm, and the thickness t7′ of the conductive layer 422 of the first electrode layer 420 may be between 0.05 μm and 0.3 μm. The thickness t8 of the intrinsic silicon layer 430 may be between 1 μm and 400 μm. In addition, the intrinsic silicon layer 430 may be a single crystal intrinsic silicon layer or a poly crystal intrinsic silicon layer, or may also contain other semiconductor material, such as GaAs.

In the present embodiment, the photovoltaic device 400 further includes an anti-reflective layer 450 which is disposed on the surface 412 of the N-type doped silicon layer 410 and exposes a portion of the second electrode layer 440. Besides, in the present embodiment, the material of the N-type doped silicon layer 410 includes single crystal silicon, poly crystal silicon, or other semiconductor material. If the intrinsic silicon layer 430 is doped with a small quantity of acceptor impurities and/or a small quantity of donor impurities, the difference between the concentration of the acceptor impurities and that of the donor impurities is less than 10 ppb and preferred to be less than 1 ppb. In addition, the maximum height roughness of a surface 432 of the intrinsic silicon layer 430 in contact with the doped silicon layer 410 and a surface 434 of the intrinsic silicon layer 430 in contact with the first electrode layer 420 may be respectively between 0.01 μm and 10 μm. Moreover, the maximum height roughness of the surface 412 of the doped silicon layer 410 is between 0.01 μm and 10 μm.

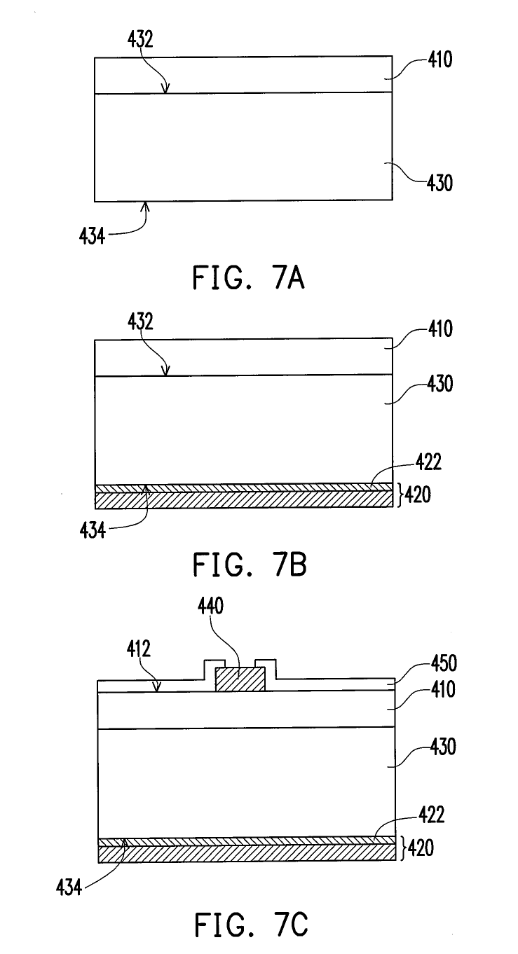

A method of manufacturing the photovoltaic device 400 in the present embodiment will be described. FIGS. 7A˜7C demonstrates schematic cross section views illustrating process flow for manufacturing the photovoltaic device according to the third embodiment of the present invention. First, referring to FIG. 7A, the N-type doped silicon layer 410 is formed on the surface 432 of the intrinsic silicon layer 430 through ion implantation, diffusion, or in-situ doped CVD. The diffusion and in-situ doped CVD process can be conducted by using the same process conditions for photovoltaic device 200. An etching process may be conducted to form two opposite rough surfaces 432 and 434 of the intrinsic silicon layer 430 before deposition of the N-type doped silicon layer 410. The etching process can be performed with solution containing KOH or NaOH. The maximum height roughness of the surfaces 432 and that of the surface 434 maybe between 0.01 μm and 10 μm respectively.

Next, referring to FIG. 7B, the first electrode layer 420 may be formed on the surface 434 of the intrinsic silicon layer 430 through sputtering, plating, or electroless plating. To be specific, the conductive layer 422 (for example, platinum) having work function higher than 5.5 eV is formed first, and then a thicker metal layer (not marked in the drawing) is formed to constitute the first electrode layer 420.

Next, referring to FIG. 7C, the second electrode layer 440 may be formed on the surface 412 of the N-type doped silicon layer 410 through sputtering, plating, or electroless plating, wherein the second electrode layer 440 may be formed through a patterning process. Next, the anti-reflective layer 450 may be formed on the surface 412 of the N-type doped silicon layer 410, wherein the anti-reflective layer 450 exposes a portion of the second electrode layer 440.

It should be noted that in the present embodiment, the photovoltaic device 400 may also be manufactured by sequentially forming the first electrode layer 420, the intrinsic silicon layer 430, the doped silicon layer 410, and the second electrode layer 440 on a substrate (not shown, the material thereof may be organic polymer, glass, ceramic, or silicon). However, such an implementation is not shown in any drawing.

It should be mentioned here that in foregoing embodiments, the order in which various components of the photovoltaic device in the present invention are formed may be changed according to the requirement of the designer as long as an intrinsic silicon region is formed in the photovoltaic device to increase the photoelectric efficiency of the photovoltaic device. Accordingly, foregoing embodiments are only used for describing the present invention but not for restricting the present invention.

In summary, the photovoltaic device in the present invention has an intrinsic silicon region so the thickness of the depletion region in the photovoltaic device in the present invention becomes very large and most of incident sunlight absorbed in the intrinsic silicon region. While sunlight irradiates the photovoltaic device, more electron-hole pairs are generated in the depletion. The electron-hole pairs can be drifted by the built-in electric field and transfer to useful electric current. Therefore, the photovoltaic device in the present invention has high photoelectric efficiency.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A photovoltaic device, comprising:
a first type doped single crystal silicon substrate;
a second type doped silicon layer;
an intrinsic silicon layer, disposed between said first type doped single crystal silicon substrate and said second type doped silicon layer, wherein the thickness of said intrinsic silicon layer is between 10 μm and 100 μm;
a first metal electrode layer, disposed on a first surface of said first type doped single crystal silicon substrate wherein said first surface is away from said intrinsic silicon layer; and
a second metal electrode layer, disposed on a second surface of said second type doped silicon layer wherein said second surface is away from said intrinsic silicon layer.

2. The photovoltaic device as claimed in claim 1, wherein said first type doped single crystal silicon substrate is a P-type doped single crystal silicon substrate, and said second type doped silicon layer is an N-type doped silicon layer.

3. The photovoltaic device as claimed in claim 1, wherein said first type doped single crystal silicon substrate is an N-type doped single crystal silicon substrate, and said second type doped silicon layer is a P-type doped silicon layer.

4. The photovoltaic device as claimed in claim 1, wherein the thickness of said first type doped single crystal silicon substrate is between 80 μm and 200 μm.

5. The photovoltaic device as claimed in claim 1, wherein the thickness of said second type doped silicon layer is between 0.05 μm and 0.5 μm.

6. The photovoltaic device as claimed in claim 1, wherein the material of said second type doped silicon layer comprises single crystal silicon or poly crystal silicon.

7. The photovoltaic device as claimed in claim 1, wherein the material of said intrinsic silicon layer comprises single crystal silicon or poly crystal silicon.

8. The photovoltaic device as claimed in claim 1, wherein said first type doped single crystal silicon substrate has a third surface in contact with said intrinsic silicon layer and the maximum height roughness of said third surface of said first type doped single crystal silicon substrate is between 0.01 μm and 10 μm.

9. The photovoltaic device as claimed in claim 1, wherein said intrinsic silicon layer comprises a plurality of acceptor impurities and a plurality of donor impurities, and the difference between the concentration of said acceptor impurities and that of said donor impurities is less than 10 ppb.

10. A photovoltaic device, comprising:
a first type doped silicon layer;
a second type doped silicon layer;
an intrinsic silicon substrate, disposed between said first type doped silicon layer and said second type doped silicon layer, wherein the thickness of said intrinsic silicon substrate is between 50 μm and 200 μm;
a first metal electrode layer, disposed on a first surface of said first type doped silicon layer, wherein said first surface is away from said intrinsic silicon substrate; and
a second metal electrode layer, disposed on a second surface of said second type doped silicon layer, wherein said second surface is away from said intrinsic silicon substrate.

11. The photovoltaic device as claimed in claim 10, wherein said first type doped silicon layer is a P-type doped silicon layer, and said second type doped silicon layer is an N-type doped silicon layer.

12. The photovoltaic device as claimed in claim 10, wherein said first type doped silicon layer is an N-type doped silicon layer, and said second type doped silicon layer is a P-type doped silicon layer.

13. The photovoltaic device as claimed in claim 10, wherein the thickness of said first type doped silicon layer is between 0.3 μm and 10 μm.

14. The photovoltaic device as claimed in claim 10, wherein the thickness of said second type doped silicon layer is between 0.03 μm and 1 μm.

15. The photovoltaic device as claimed in claim 10, wherein the thickness of said first type doped silicon layer is between 0.3 μm and 1 μm.

16. The photovoltaic device as claimed in claim 10, wherein the thickness of said second type doped silicon layer is between 0.05 μm and 0.5 μm.

17. The photovoltaic device as claimed in claim 10, wherein the material of said first type doped silicon layer comprises single crystal silicon or poly crystal silicon.

18. The photovoltaic device as claimed in claim 10, wherein the material of said second type doped silicon layer comprises single crystal silicon or poly crystal silicon.

19. The photovoltaic device as claimed in claim 10, wherein said intrinsic silicon substrate has a third surface in contact with said first type doped silicon layer and the maximum height roughness of said third surface of said intrinsic silicon substrate is between 0.01 μm and 10 μm.

20. The photovoltaic device as claimed in claim 10, wherein the maximum height roughness of said second surface of said second type doped silicon layer is between 0.01 μm and 10 μm.

21. The photovoltaic device as claimed in claim 10, wherein said intrinsic silicon substrate comprises a plurality of acceptor impurities and a plurality of donor impurities, and the difference between the concentration of said acceptor impurities and that of said donor impurities is less than 10 ppb.

22. A photovoltaic device, comprising:
an N-type doped silicon layer;
a first electrode layer, having a conductive layer, wherein the work function of said conductive layer is higher than 5.5 eV;
an intrinsic silicon layer, disposed between said N-type doped silicon layer and said first electrode layer, wherein said conductive layer is in direct contact with said intrinsic silicon layer; and
a second electrode layer, disposed on a first surface of said N-type doped silicon layer wherein said first surface is away from said intrinsic silicon layer.

23. The photovoltaic device as claimed in claim 22, wherein the material of said conductive layer comprises platinum.

24. The photovoltaic device as claimed in claim 22, wherein the thickness of said N-type doped silicon layer is between 0.05 μm and 1 μm.

25. The photovoltaic device as claimed in claim 22, wherein the thickness of said first electrode layer is between 0.03 μm and 10 μm.

26. The photovoltaic device as claimed in claim 22, wherein the thickness of said N-type doped silicon layer is between 0.05 μm and 0.5 μm.

27. The photovoltaic device as claimed in claim 22, wherein the thickness of said conductive layer is between 0.05 μm and 0.3 μm.

28. The photovoltaic device as claimed in claim 22, wherein the thickness of said intrinsic silicon layer is between 1 μm and 400 μm.

29. The photovoltaic device as claimed in claim 22, wherein the material of said N-type doped silicon layer comprises single crystal silicon or poly crystal silicon.

30. The photovoltaic device as claimed in claim 22, wherein said intrinsic silicon layer comprises a plurality of acceptor impurities and a plurality of donor impurities, and the difference between the concentration of said acceptor impurities and that of said donor impurities is less than 10 ppb.
